(19) United States
(12) Patent Application Publication
(10) Pub. No.: US 2026/0250806 A1
(43) Pub. Date: Aug. 27, 2026

(54) CEMENTED CARBIDE, COATED CEMENTED CARBIDE, AND TOOL HAVING THE SAME

(71) Applicant: TUNGALOY CORPORATION, Fukushima (JP)

(72) Inventor: Tomoaki SHOJI, Fukushima (JP)

(73) Assignee: TUNGALOY CORPORATION, Fukushima (JP)

(21) Appl. No.: 19/535,701

(22) Filed: Feb. 10, 2026

(30) Foreign Application Priority Data
Feb. 21, 2025 (JP) 2025-026344

(51) Int. Cl. C22C 29/08; B23B 27/14; C22C 29/00; C23C 14/06; C23C 14/28

(52) U.S. Cl. CPC C22C 29/08; B23B 27/148; C22C 29/005; B23B 2228/105; C23C 14/0641; C23C 14/0664; C23C 14/28

(57) ABSTRACT

A cemented carbide and a coated cemented carbide having a long tool life with improved wear resistance and fracture resistance, as well as a cutting tool having the same are provided.

A cemented carbide comprises a WC phase, a binder phase, and a hard phase in their respective predetermined content ratios. The WC phase comprises WC, the binder phase comprises a predetermined element, and the hard phase comprises a predetermined compound. In the WC phase, a region between measurement points where a misorientation between adjacent measurement points measured by an EBSD method is 5° or more is referred to as a grain boundary between adjacent WC grains, and the grain boundary between WC grains is referred to as a grain boundary A, a grain boundary except for a Σ2 grain boundary of the grain boundary A is referred to as a grain boundary B, a grain diameter at which a cumulative value in a grain number-based grain size distribution using the grain boundary A becomes 10% is referred to as D_{10A}, and a grain diameter at which a cumulative value in a grain number-based grain size distribution using the grain boundary B becomes 10% is referred to as D_{10B}. Thus, a ratio of the D_{10B} to the D_{10A} (D_{10B}/D_{10A}) is 1.30 or more and 2.00 or less, and a ratio of a length of the Σ2 grain boundary to a length of the grain boundary A is 5.0% or more and less than 15.0%.

### FIELD OF THE INVENTION

The present invention relates to a cemented carbide, a coated cemented carbide, and a tool having the same.

### DESCRIPTION OF RELATED ART

Conventionally, a cemented carbide including a phase containing tungsten carbide (WC) as a main component, and a binder phase containing iron group elements as a main component has been used as a material for cutting tools. Accordingly, for the purpose of providing cutting tools made of a cemented carbide with a long tool life, various proposals have been made.

For example, Patent Publication JP-A-2021-139032 proposes a WC-based cemented carbide including at least one of Co and Ni in an amount of 4.0 mass % or more and less than 10.0 mass %; at least one or more selected from TiC, TaC, NbC, ZrC, HfC, and VC in a total amount of 4.0 mass % or more and less than 12.0 mass %; and Cr₃C₂ in an amount of 0.0 mass % or more and less than 0.5 mass %, the balance including WC and inevitable impurities, in which the average grain diameter of WC is 0.2 μm or more and 4.0 μm or less, and the abundance ratio of the Σ2-related grain boundary of WC in all WC/WC grain boundaries (Σ2-related grain boundary ratio) is 15% or more, and a cutting tool using the cemented carbide.

Further, for example, Patent Publication JP-A-2014-105353 proposes a WC-based cemented carbide including WC grains as a main hard phase, in which the hard phases are bonded by a binder phase including an iron group metal as a main component, and includes a fine grain layer including WC grains having an average grain diameter of 1 μm or less as a hard phase on the front surface side, and a coarse grain layer including WC grains having an average grain diameter of 2 μm or more as a hard phase on the inner side, the thickness of the fine grain layer is 200 μm or more and 1000 μm or less, and a<15 mass % and 1.0<a/b<2.0 is satisfied, where a represents the content of the binder phases in the fine grain layer, and b represents the content of the binder phases in the coarse grain layer, and a cutting tool using the cemented carbide.

### SUMMARY

There are increasing opportunities to process difficult-to-machine materials such as titanium alloys used for use in aircraft components, and the like, nickel-based heat resistant alloys, cobalt-based heat resistant alloys, and the like for use in a turbine blade for a generator, by cutting process. In cutting process of a difficult-to machine material having a low thermal conductivity such as a nickel-based heat resistant alloy or a cobalt-based heat resistant alloy, the cutting temperature tends to become high. In such high-temperature process, the strength of the cutting edge of a cutting tool decreases, thereby causing fracture. For this reason, the tool life undesirably becomes extremely shorter as compared with conventional processing of general steel.

Under such circumstances, for the cemented carbide according to Patent Publication JP-A-2021-139032, while the proportion of the Σ2 grain boundaries increases, a triple point tends to be formed among WC grains, and there is room for improvement in fracture resistance. In addition, the cemented carbide of Patent Publication JP-A-2014-105353 has the following problem: the strength among WC grains in the fine grain layer is insufficient, so that the grains drop, thereby causing the progress of wear and fracture. Further, since the fine grain layer has insufficient heat resistance, wear due to plastic deformation may occur. Further, since the fine grain layer and the coarse grain layer are different from each other in the content ratio of the binder phases, cracks tend to be formed between the fine grain layer and the coarse grain layer after sintering and/or during processing, so that there is room for improvement in fracture resistance.

The present invention was made in view of the above circumstances, and it is an object of the present invention to provide a cemented carbide and a coated cemented carbide improved in wear resistance and fracture resistance, and having a long tool life, and a tool having the same.

The present inventors conducted a close study on the extension of the tool life of a tool having a cemented carbide and a coated cemented carbide. As a result, they found the following: a cemented carbide and a coated cemented carbide is allowed to have a specific configuration; this enables the improvement of the wear resistance and the fracture resistance; as a result, the tool life of a tool having a cemented carbide and a coated cemented carbide can be extended. This has led to the completion of the present invention.

That is, the gist of the present invention includes the following contents.
[1] A cemented carbide including a WC phase, a binder phase, and a hard phase, in which
   the WC phase comprises WC;
   the binder phase comprises at least one selected from the group consisting of Co, Ni, and Fe;
   the hard phase comprises at least one of a carbide, a nitride, and a carbonitride of at least one element selected from the group consisting of Ti, V, Cr, Zr, Nb, Mo, Hf, and Ta;
   the content ratio of the WC phases is 80.0 mass % or more and 95.0 mass % or less, the content ratio of the binder phases is 4.0 mass % or more and 15.0 mass % or less, and the content ratio of the hard phases is 0.1 mass % or more and 6.0 mass % or less, relative to 100 mass % of the entire cemented carbide;
   when in the WC phase, the grain boundary between measurement points where the misorientation between adjacent measurement points measured by the electron backscatter diffraction (EBSD) method is 5° or more is referred to as the grain boundary between adjacent WC grains, the grain boundary between the WC grains is referred to as a grain boundary A, the grain boundary except for the Σ2 grain boundary of the grain boundary A is referred to as a grain boundary B, the grain diameter at which the cumulative value in the grain number-based grain size distribution using the grain boundary A becomes 10% is referred to as D_{10A}, and the grain diameter at which the cumulative value in the grain number-based grain size distribution using the grain boundary B becomes 10% is referred to as D_{10B},
   the ratio of the D_{10B} to the D_{10A} (D_{10B}/D_{10A}) is 1.30 or more and 2.00 or less; and
   the ratio of the length of the Σ2 grain boundaries to 100% of the length of the grain boundaries A is 5.0% or more and less than 15.0%.
[2] The cemented carbide according to [1], in which the ratio (D_{90B}/D_{90A}) of the D_{90B} to the D_{90A} is less than 1.30, where D_{90A} represents the grain diameter at which the cumulative value in the grain number-based grain size distribution using the grain boundary A becomes 90%, D_{90B} represents a grain diameter at which the cumulative value in a grain number-based grain size distribution using the grain boundary B becomes 90%.
[3] The cemented carbide according to [2], in which
   the D_{90A} is 0.50 μm or more and 2.00 μm or less.
[4] The cemented carbide according to any one of [1] to [3], in which
   the D_{10A} is 0.05 μm or more and 0.30 μm or less.
[5] A coated cemented carbide having the cemented carbide according to any one of [1] to [4], and a coating layer disposed on a surface of the cemented carbide, in which
   the coating layer is a monolayer or a lamination of two or more layers including a compound including at least one element selected from the group consisting of Ti, Zr, Hf, V, Nb, Ta, Cr, Mo, W, Al, Si, and Y and at least one element selected from the group consisting of C, N, O, and B, and
   the average thickness of the entire coating layer is 0.5 μm or more and 10.0 μm or less.
[6] A tool having the cemented carbide according to any one of [1] to [4], or the coated cemented carbide according to [5].

According to the present invention, it is possible to provide a cemented carbide and a coated cemented carbide improved in wear resistance and fracture resistance, and having a long tool life, and a tool having the same.

### BRIEF DESCRIPTION OF DRAWINGS

FIG. 1 is a schematic diagram for illustrating a method for identifying grains A and grains B by the EBSD method.

### DETAILED DESCRIPTION

Hereinafter, embodiments for carrying out the present invention (hereinafter simply referred to as “the present embodiment”) will be described in detail, but the present invention is not limited to the present embodiments below. The present invention can be modified in various manners within the scope not departing from the gist thereof.

### Cemented Carbide

A cemented carbide of the present embodiment is a cemented carbide including a WC phase, a binder phase, and a hard phase, in which
the WC phase includes WC;
the binder phase includes at least one selected from the group consisting of Co, Ni, and Fe;
the hard phase includes at least one of a carbide, a nitride, and a carbonitride of one or more selected from the group consisting of Ti, V, Cr, Zr, Nb, Mo, Hf, and Ta;
the content ratio of the WC phases is 80.0 mass % or more and 95.0 mass % or less, the content ratio of the binder phases is 4.0 mass % or more and 15.0 mass % or less, and the content ratio of the hard phases is 0.1 mass % or more and 6.0 mass % or less, relative to 100 mass % of the entire cemented carbide; and
when in the WC phase, the grain boundary between measurement points where the misorientation between adjacent measurement points measured by the electron backscatter diffraction (EBSD) method is 5° or more is referred to as the grain boundary between adjacent WC grains, and the grain boundary between the WC grains is referred to as a grain boundary A, the grain boundary except for the Σ2 grain boundary of the grain boundary A is referred to as a grain boundary B, the grain diameter at which the cumulative value in the grain number-based grain size distribution using the grain boundary A becomes 10% is referred to as D_{10A}, and the grain diameter at which the cumulative value in the grain number-based grain size distribution using the grain boundary B becomes 10% is referred to as D_{10B},
the ratio of the D_{10B} to the D_{10A} (D_{10B}/D_{10A}) is 1.30 or more and 2.00 or less; and
the ratio of the length of the Σ2 grain boundaries to 100% of the length of the grain boundaries A is 5.0% or more and less than 15.0%.

Although the factor resulting in such a cemented carbide improved in wear resistance and fracture resistance is not clear in detail, the present inventors infer that the following factors might be combined. However, the factors are not limited thereto.

When the WC phase includes WC and the content ratio of the WC phases is 80.0 mass % or more relative to 100 mass % of the entire cemented carbide, the hardness is improved. For this reason, the wear resistance is excellent. The content ratio of the WC phases is 95.0 mass % or less, the toughness is improved. For this reason, the fracture resistance is excellent.

When the binder phase includes at least one selected from the group consisting of Co, Ni, and Fe, and the content ratio of the binder phases is at least 4.0 mass % or more relative to 100 mass % of the entire cemented carbide, the toughness is improved. For this reason, the fracture resistance is excellent. When the content ratio of the binder phases is 15.0 mass % or less, the hardness is improved. For this reason, the wear resistance is excellent.

When the hard phase includes at least one of a carbide, a nitride, or a carbonitride of one or more selected from the group consisting of Ti, V, Cr, Zr, Nb, Mo, Hf, and Ta, and the content ratio of the hard phases is 0.1 mass % or more relative to 100 mass % of the entire cemented carbide, the plastic deformation resistance is improved. For this reason, the wear resistance is excellent. The content ratio of the hard phases is 6.0 mass % or less, the toughness is improved. For this reason, the fracture resistance is excellent.

When the ratio of D_{10B} to D_{10A} (D_{10B}/D_{10A}) is 1.30 or more, where in the WC phase, the grain boundary between measurement points where the misorientation between adjacent measurement points measured by the EBSD method is 5° or more is referred to as the grain boundary between adjacent WC grains, and the grain boundary between the WC grains is referred to as a grain boundary A, the grain boundary of the WC grains except for the Σ2 grain boundary of the grain boundary A is referred to as a grain boundary B, the grain diameter at which the cumulative value in the grain number-based grain size distribution using the grain boundary A becomes 10% is referred to as D_{10A}, and the grain diameter at which the cumulative value in the grain number-based grain size distribution using the grain boundary B becomes 10% is referred to as D_{10B}, fine WC grains are adjacent to other WC grains via the Σ2 grain boundaries, so that the heat resistance is improved and the drop-off of grains is also suppressed. For this reason, the wear resistance and the fracture resistance are excellent. When the ratio (D_{10B}/D_{10A}) is 2.00 or less, the stress concentration due to the pinning effect of grain boundary slip is relaxed in fine WC grains. For this reason, the fracture resistance is excellent.

When the ratio of the length of the Σ2 grain boundaries to 100% of the length of the grain boundaries A is 5.0% or more, the bonding force among the WC grains is increased, thereby improving the plastic deformation resistance. For this reason, the wear resistance is excellent. When the ratio of the length of the Σ2 grain boundaries to 100% of the length of grain boundaries A is less than 15.0%, the formation of the triple point as the starting point of fracture among the WC grains is suppressed. For this reason, the fracture resistance is improved.

A cemented carbide of the present embodiment includes a WC phase, a binder phase, and a hard phase. The content ratio of the WC phases is 80.0 mass % or more and 95.0 mass % or less, the content ratio of the binder phases is 4.0 mass % or more and 15.0 mass % or less, and the content ratio of the hard phases is 0.1 mass % or more and 6.0 mass % or less, relative to 100 mass % of the entire cemented carbide.

In the cemented carbide of the present embodiment, the content ratios (mass %) of the WC phases, the binder phases, and the hard phases can be determined by observing an arbitrary cross-sectional structure with a scanning electron microscope (SEM) with an energy dispersive X-ray spectrometer (EDS), and measuring each composition of the cemented carbide by EDS. Specifically, the content ratios can be determined by a method described in Examples below.

### WC Phase

In the cemented carbide of the present embodiment, the WC phase includes WC, and preferably consists of WC. When the WC phase includes WC and the content ratio of the WC phases is 80.0 mass % or more relative to 100 mass % of the entire cemented carbide, the hardness is improved. For this reason, the wear resistance is excellent. On the other hand, when the content ratio of the WC phases is 95.0 mass % or less, the toughness is improved. For this reason, the fracture resistance is excellent. From the same viewpoint, the content ratio of the WC phases is preferably 80.5 mass % or more and 94.5 mass % or less, and more preferably 83.5 mass % or more and 92.8 mass % or less.

### Length of Grain Boundary Between WC Grains

Between adjacent WC grains, there are a crystal grain boundary having a relatively higher grain boundary energy and a crystal grain boundary having a relatively lower grain boundary energy. Usually, in the grain boundaries, the arrangement of atoms is irregularly disordered, and random array is caused, so that the grain boundaries have a large number of gaps and have a relatively higher grain boundary energy. On the other hand, in crystal grain boundaries, in some grain boundaries, the arrangement of atoms is regular and the number of gaps is small, and such grain boundaries have a relatively lower grain boundary energy. A typical example of a crystal grain boundary having a relatively lower grain boundary energy may include a coincidence site lattice crystal grain boundary, which is also referred to as a related grain boundary. The Σ value is known as an index indicating the degree of distribution of the corresponding grain boundaries, and is defined as the ratio of the crystal lattice point densities of two crystal grains in contact with each other at the grain boundary and the density of lattice points to be in agreement with each other when both crystal lattices are superposed. In the case of a simple structure, it is generally observed that grain boundaries with a low Σ value tend to have a low interfacial energy and special characteristics. Therefore, it is very important to understand the influence of the ratio of the corresponding grain boundaries and the distribution of the grain misorientations for the improvement of the characteristics of a cemented carbide.

In the case where in the WC phase of the cemented carbide of the present embodiment, the grain boundary between measurement points where the misorientation between adjacent measurement points measured by the electron backscatter diffraction (EBSD) method is 5° or more is referred to as the grain boundary between adjacent WC grains, the grain boundary between the WC grains is referred to as a grain boundary A, the grain boundary of the WC grains except for the Σ2 grain boundary of the grain boundary A is referred to as a grain boundary B, the grain diameter at which the cumulative value in the grain number-based grain size distribution using the grain boundary A becomes 10% is referred to as D_{10A}, and the grain diameter at which the cumulative value in the grain number-based grain size distribution using the grain boundary B becomes 10% is referred to as D_{10B}, when the ratio of the D_{10B} to the D_{10A} (D_{10B}/D_{10A}) is 1.30 or more, fine WC grains are adjacent to other WC grains via the Σ2 grain boundaries. As a result, the heat resistance is improved and the drop-off of grains is suppressed, and hence, the wear resistance and the fracture resistance are excellent. On the other hand, when the ratio (D_{10B}/D_{10A}) is 2.00 or less, the stress concentration due to pinning effect of grain boundary slip is relaxed in fine WC grains, resulting in excellent fracture resistance. From the same viewpoint, the ratio (D_{10B}/D_{10A}) is preferably 1.31 or more and 1.84 or less, more preferably 1.34 or more and 1.83 or less, and still more preferably 1.42 or more and 1.75 or less. In the present embodiment, the misorientation of each measuring point can be determined by the method described in the embodiment described later with reference to the misorientation of crystal orientations obtained by measuring the WC phase by an electron backscatter diffraction (EBSD) method.

When the ratio of the length of the Σ2 grain boundary to 100% of the length of the grain boundaries A is 5.0% or more, the bonding force among the WC grains is increased, thereby improving the plastic deformation resistance. For this reason, the wear resistance is excellent. On the other hand, when the ratio of the length of Σ2 grain boundaries to 100% of the length of the grain boundaries A is less than 15.0%, the formation of the triple point serving as the starting point of breakage among the WC grains is suppressed. For this reason, the fracture resistance is improved. From the same viewpoint, the ratio of the length of the Σ2 grain boundaries to 100% of the length of the grain boundaries A is preferably 6.2% or more and 14.6% or less, and more preferably 8.0% or more and 14.2% or less. Incidentally, the ratio of the lengths of the grain boundaries can be determined by for example, the method described in Examples below.

The D_{10A} is preferably 0.05 μm or more and 0.30 μm or less. When the D_{10A} is 0.05 μm or more, drop-off of the WC grains is suppressed. For this reason, the wear resistance and the fracture resistance tend to be excellent. On the other hand, when the D_{10A} is 0.30 μm or less, the frequency of adjacency of the WC grains increases. For this reason, the effect obtainable by setting the ratio (D_{10B}/D_{10A}) at 1.30 or more tends to be exhibited more effectively and reliably. From the same viewpoint, the D_{10A} is more preferably 0.06 μm or more and 0.28 μm or less, and still more preferably 0.07 μm or more and 0.24 μm or less.

The D_{10B} is preferably 0.07 μm or more and 0.60 μm or less. When the D_{10B} is 0.07 μm or more, drop-off of the WC grains is suppressed. For this reason, the wear resistance and the fracture resistance tend to be excellent. When the D_{10B} is 0.60 μm or less, the hardness is improved. For this reason, the wear resistance tends to be excellent. From the same viewpoint, the D_{10B} is more preferably 0.09 μm or more and 0.42 μm or less, and still more preferably 0.10 μm or more and 0.36 μm or less.

When the ratio (D_{90B}/D_{90A}) of D_{90B} to D_{90A} is less than 1.30, where D_{90A} represents the grain diameter at which the cumulative value in the grain number-based grain size distribution using the grain boundary A becomes 90%, and D_{90B} represents the grain diameter at which the cumulative value in the grain number-based grain size distribution using the grain boundary B becomes 90%, between the coarse WC grains, the formation of the triple point serving as the starting point of breakage is suppressed. For this reason, the fracture resistance tends to be excellent. Further, the ratio (D_{90B}/D_{90A}) may be, for example, 1.00 or more. From the same viewpoint, the ratio (D_{90B}/D_{90A}) is preferably 1.00 or more and 1.25 or less, more preferably 1.00 or more and 1.24 or less, and still more preferably 1.00 or more and 1.19 or less.

The D_{90A} is preferably 0.50 μm or more and 2.00 μm or less. When the D_{90A} is 0.50 μm or more, the heat resistance is improved. For this reason, the wear resistance tends to be excellent. On the other hand, when the D_{90A} is 2.00 μm or less, the hardness is improved. For this reason, the wear resistance tends to be excellent. From the same viewpoint, the D_{90A} is more preferably 0.54 μm or more and 1.96 μm or less, and still more preferably 0.62 μm or more and 1.80 μm or less.

The D_{90B} is preferably 0.50 μm or more and 2.60 μm or less. When the D_{90B} is 0.50 μm or more, the heat resistance is improved. For this reason, the wear resistance tends to be excellent. When the D_{90B} is 2.60 μm or less, the hardness is improved. For this reason, the wear resistance tends to be excellent. From the same viewpoint, the D_{90B} is more preferably 0.58 μm or more and 2.16 μm or less, and still more preferably 0.68 μm or more and 2.00 μm or less.

Incidentally, in the present embodiment, the length of the grain boundary between WC grains, the grain diameter based on each grain boundary, and the ratio thereof can be determined by the method described in Examples described later.

### Binder Phase

In the cemented carbide of the present embodiment, the binder phase includes at least one selected from the group consisting of Co, Ni, and Fe. Inclusion of such a binder phase in cemented carbide improves the toughness. For this reason, the fracture resistance is excellent. From the same viewpoint, the binder phase preferably includes at least one of Co or Ni, and more preferably includes Co.

In the cemented carbide of the present embodiment, when the content ratio of the binder phases is 4.0 mass % or more relative to 100 mass % of the entire cemented carbide, the toughness is improved. For this reason, the fracture resistance is excellent. On the other hand, when the content ratio of the binder phases is 15.0 mass % or less, the hardness is improved. For this reason, the wear resistance is excellent. From the same viewpoint, the content ratio of the binder phases is preferably 4.5 mass % or more and 14.0 mass % or less, and more preferably 7.0 mass % or more and 13.5 mass % or less.

In the cemented carbide of the present embodiment, the content ratio of Co included in the binder phase is preferably 4.0 mass % or more and 15.0 mass % or less relative to 100 mass % of the entire cemented carbide. When the content ratio of Co is 4.0 mass % or more, the toughness is improved. For this reason, the fracture resistance tends to be excellent. On the other hand, when the content ratio of Co is 15.0 mass % or less, the hardness and the plastic deformation resistance are improved. For this reason, the wear resistance tends to be excellent. From the same viewpoint, the content ratio of Co included in the binder phase is more preferably 4.5 mass % or more and 13.5 mass % or less, and still more preferably 5.0 mass % or more and 10.0 mass % or less.

### Hard Phase

In the cemented carbide of the present embodiment, the hard phase includes at least one of a carbide, a nitride, or a carbonitride of one or more selected from the group consisting of Ti, V, Cr, Zr, Nb, Mo, Hf, and Ta. Inclusion of such a hard phase in cemented carbide improves the plastic deformation resistance. For this reason, the wear resistance is excellent. From the same viewpoint, the hard phase preferably includes at least one of a carbide, a nitride, or a carbonitride of one or more selected from the group consisting of Ti, Cr, Zr, Nb, and Ta, more preferably includes at least one of a carbide or a carbonitride of one or more selected from the group consisting of Ti, Cr, Zr, Nb, and Ta, and still more preferably includes at least one selected from the group consisting of TiC, NbC, TaC, ZrC, and Cr₃C₂.

When the content ratio of the hard phases in the cemented carbide of the present embodiment is 0.1 mass % or more relative to 100 mass % of the entire cemented carbide, the plastic deformation resistance is improved. For this reason, the wear resistance is excellent. On the other hand, when the content ratio of the hard phases is 6.0 mass % or less, the toughness is improved. For this reason, the fracture resistance is excellent. From the same viewpoint, the content ratio of the hard phases is preferably 0.2 mass % or more and 5.5 mass % or less, and more preferably 1.0 mass % or more and 3.0 mass % or less.

The cemented carbide of the present embodiment may include components other than the WC phase, the binder phase, and the hard phase as long as the function and effect of the present invention are not impaired. For example, the cemented carbide may include B, C, N, and/or O element in an amount of 1 mass % or less relative to 100 mass % of the entire cemented carbide as impurities included in the raw material powder. From the viewpoint of exhibiting the effect by the present invention still more effectively and reliably, the total content ratio of the three phases of the WC phase, the binder phase, and the hard phase is preferably 99 mass % or more and 100 mass % or less, and more preferably 100 mass % relative to 100 mass % of the entire cemented carbide. Further, the cemented carbide may include a free carbon or a η phase in its structure in an amount of 1 vol % or less relative to 100 vol % of the entire cemented carbide. From the viewpoint of exhibiting the effects by the present invention still more effectively and reliably, the total content ratio of the three phases of the WC phase, the binder phase, and the hard phase is preferably 99 vol % or more and 100 vol % or less, and more preferably 100 vol % relative to 100 vol % of the entire cemented carbide.

### Method for Manufacturing Cemented Carbide

The cemented carbide of the present embodiment can be manufactured by, for example, the following method.

As the raw material powder, if required, a WC powder having an average particle diameter of 0.3 μm to 3.0 μm, a Co powder having an average particle diameter of 1.0 μm to 3.0 μm, a Ni powder having an average particle diameter of 1.0 μm to 3.0 μm, a TiC powder having an average particle diameter of 0.7 μm to 1.5 μm, a NbC powder having an average particle diameter of 0.8 μm to 1.2 μm, a TaC powder having an average particle diameter of 0.8 μm to 1.2 μm, a ZrC powder having an average particle diameter of 3.0 μm to 5.0 μm, and a Cr₃C₂ powder having an average particle diameter of 1.0 μm to 2.0 μm, or the like is prepared and blended (Blending step).

Here, when a material having a high carbon content is used as a raw material powder of WC, the ratio of the length of the Σ2 grain boundaries to the length of the grain boundaries A, the ratio (D_{10B}/D_{10A}) and the ratio (D_{90B}/D_{90A}) tend to increase. When the average particle diameter of the WC raw material powder is increased, the D_{10A} and the D_{90A} tend to increase.

Then, the mixture obtained by blending respective powders in their respective required amounts is mixed with a solvent and a ball made of cemented carbide for 6 hours to 16 hours by a planetary ball mill, resulting in a mixture (mixing step). The solvent is vaporized while heating and drying the resulting mixture at 100° C. or less, resulting in a dried mixture (drying step). A paraffin wax is blended in an amount of 1.5 mass % relative to the dried mixture, and the mixture is molded into a predetermined tool shape (molding step).

Here, when the time for performing the mixing step is elongated, the D_{10A} and the D_{90A} tend to be reduced.

Then, the molded body obtained in the molding step is accommodated in a sintering furnace, and is raised in temperature up to 1300° C. in a vacuum atmosphere at 70 Pa or less (first temperature raising step). When the first temperature raising step is performed, degassing is promoted, and sinterability in the subsequent sintering step tends to be improved. Further, under an inert gas atmosphere at 100 kPa to 1000 kPa (such as Ar), the temperature is raised up to 1400° C. to 1600° C. at a rate of 1° C./min to 10° C./min (second temperature raising step). Subsequently, the sample is held at a temperature of 1400° C. to 1600° C. for 20 minutes to 60 minutes under an inert gas (such as Ar) atmosphere at 60 kPa to 300 kPa, and is sintered (sintering step).

After the sintering step, under a mixed gas atmosphere of Ar and CO with a total pressure of 60 kPa to 300 kPa, the sample is cooled to a temperature of a liquid phase temperature or lower (e.g., 1250° C. or lower) at a rate of 1° C./min to 8° C./min (first cooling step). The partial pressure ratio of Ar:CO of the mixed gas in the first cooling step may be, for example, 7:3 to 9:1. The sintered body after the first cooling step, is controlled and cooled to a predetermined temperature, for example, at a rate of 50° C./min, in an inert gas (such as Ar) atmosphere at atmospheric pressure, and is further cooled down to room temperature (second cooling step).

Herein, when the partial pressure of CO in the first cooling step is increased, the ratio of the length of the Σ2 grain boundaries to the length of grain boundaries A and the ratio (D_{10B}/D_{10A}) tend to increase. Whereas, in the case where a mixed gas of Ar and CO is used in the first cooling step, when the cooling rate is decreased, the ratio of the length of the Σ2 grain boundary to the length of grain boundaries A, and the ratio (D_{10B}/D_{10A}) and the ratio (D_{90B}/D_{90A}) tend to increase. Furthermore, in the case where Ar gas is used and a CO gas is not used in the first cooling step, when the cooling rate is reduced, the ratio of the length of the Σ2 grain boundaries to the length of grain boundary A, and the ratio (D_{90B}/D_{90A}) tend to increase.

### Coated Cemented Carbide

It is preferable that the cemented carbide of the present embodiment is configured as a coated cemented carbide that further includes a coating layer disposed on the surface thereof. Inclusion of the coating layer tends to result in still more excellent wear resistance and fracture resistance.

In the coated cemented carbide of the present embodiment, the coating layer is a monolayer or a lamination of two or more layers including a compound including at least one element selected from the group consisting of Ti, Zr, Hf, V, Nb, Ta, Cr, Mo, W, Al, Si, and Y, and at least one element selected from the group consisting of C, N, O, and B. By configuring the coating layer with the configuration as described above, the wear resistance and the fracture resistance tend to be still more excellent. From the viewpoint of exhibiting the same effect still more effectively and reliably, as the compound in the coating layer, a compound including at least one element selected from the group consisting of Ti, Zr, V, Nb, Cr, Mo, W, Al, and Si, and at least one element selected from a group consisting of C, N, and B is preferably used, and a compound including at least one element selected from the group consisting of Ti, Nb, Cr, W, Al, and Si, and at least one element selected from the group consisting of C and N is more preferably used.

Specific examples of the compound layer in the coating layer may include, for example, a TiN layer, a TiCN layer, a CrN layer, a NbN layer, a (Ti_{0.5}Al_{0.5})N layer, an (Al_{0.6}Ti_{0.4})N layer, an (Al_{0.67}Ti_{0.33})N layer, an (Al_{0.7}Ti_{0.3})N layer, an (Al_{0.8}Ti_{0.2})N layer, an (Al_{0.7}Cr_{0.3})N layer, an (Al_{0.8}Cr_{0.2})N layer, a (Ti_{0.9}Si_{0.1})N layer, an (Al_{0.65}Ti_{0.25}Si_{0.1})N layer, and a (Ti_{0.6}Al_{0.3}W_{0.1})N layer.

In the coated cemented carbide of the present embodiment, the average thickness of the entire coating layer is 0.5 μm or more and 10.0 μm or less. When the average thickness of the entire coating layer is 0.5 μm or greater, the wear resistance tends to be further improved, and when the average thickness is 10.0 μm or less, the peeling of the coating layer tends to be suppressed, so that the fracture resistance tends to be further improved. From the same viewpoint, the average thickness of the entire coating layer is preferably 1.5 μm or more and 7.5 μm or less, and more preferably 2.0 μm or more and 4.0 μm or less.

The average thickness of each layer when two or more layers are stacked in the coating layer is not particularly limited so long as the effect of the present invention is not impaired. The average thickness of each layer may be, for example, 0.2 μm or more and 5.0 μm or less, and may be 0.5 μm or more and 3.5 μm or less.

The compound layer may have a structure in which a plurality of layers having different compositions are alternately stacked. In this case, the average thickness per layer in each layer is, for example, 5 nm or more and 500 nm or less.

The average thickness of respective layers configuring the coating layer and the average thickness of the entire coating layer can be measured from the cross-sectional structure of the coated cemented carbide using an optical microscope, a SEM, a transmission electron microscope (TEM), or the like. Incidentally, the average thickness of respective layers and the average thickness of the entire coating layer in the coated cemented carbide of the present embodiment can be determined by, for example, measuring the thickness of each layer and the thicknesses of the entire coating layer from the cross sections at at least three or more sites, and calculating the average value thereof.

In addition, in the coated cemented carbide of the present embodiment, the composition of each layer configuring the coating layer can be determined from the cross-sectional structure of the coated cemented carbide by the measurement using an EDS, a wavelength dispersive X-ray analyzer (WDS), or the like.

### Method for Forming Coating Layer

The method for forming the coating layer in the coated cemented carbide of the present embodiment is not particularly limited. Examples thereof may include a chemical vapor deposition method and physical vapor deposition methods such as an ion plating method, an arc ion plating method, a sputtering method, and an ion mixing method. Among them, the physical vapor deposition method is preferable because the adhesion between the coating layer and the cemented carbide is still more excellent, and the arc ion plating method is more preferable.

### Physical Vapor Deposition Method

The respective compound layers constituting the coating layer may be formed by using, for example, the following physical vapor deposition method (arc ion plating method) on the surface of the cemented carbide of the present embodiment processed into a tool shape.

The cemented carbide of the present embodiment is accommodated in a reaction vessel of a physical vapor deposition apparatus, and the inside of the reaction vessel is evacuated until the pressure may become a vacuum of 1.0×10⁻² Pa or less. After evacuation, the cemented carbide is heated by a heater in the reaction vessel until the temperature thereof may become 200° C. or more and 800° C. or less. After heating, an Ar gas is introduced into the reaction vessel, and the pressure in the reaction vessel is adjusted to 0.5 Pa or more and 5.0 Pa or less. A bias voltage of −1000 V or more and −200 V or less is applied to the cemented carbide under an Ar gas atmosphere at a pressure of 0.5 Pa or more and 5.0 Pa or less, and a current of 10 A or more and 60 A or less is passed through a tungsten filament in the reaction vessel. Thus, an ion bombardment treatment with an Ar gas is performed on the surface of the cemented carbide. After subjecting the surface of the cemented carbide to an ion bombardment treatment, the inside of the reaction vessel is evacuated until the pressure may become a vacuum of 1.0×10⁻² Pa or lower.

Next, the cemented carbide is controlled until the temperature thereof may become 200° C. or more and 600° C. or less. Then, a reaction gas such as a nitrogen gas is introduced into the reaction vessel as required, and the pressure in the reaction vessel is adjusted to 0.5 Pa or more and 5.0 Pa or less. Then, a bias voltage of −150 V or more and −10 V or less is applied to the cemented carbide, and the metal evaporation source corresponding to the metal component of the coating layer is evaporated by arc discharge of 80 A or more and 180 A or less, thereby forming a coating layer on the surface of the cemented carbide. Thus, a coated cemented carbide is obtained.

### Tool

The tool of the present embodiment includes the cemented carbide or the coated cemented carbide. The tool of the present embodiment may include the same configuration as that of known tools except for having the cemented carbide or coated cemented carbide. The cemented carbide or the coated cemented carbide of the present embodiment is excellent in wear resistance and fracture resistance. For this reason, the tool having them can be used as, for example, a cutting tool or a wear resistant tool, and among them, the tool is preferably used as a cutting tool. It is further preferable that the cemented carbide or the coated cemented carbide of the present embodiment is used as a cutting tool for a difficult-to machine material having a low thermal conductivity. When the cemented carbide or the coated cemented carbide of the present embodiment is used as a cutting tool or a wear resistant tool, the tool life can be extended more than in the prior art.

### EXAMPLES

Below, the present invention will be further described in detail by way of Examples. However, the present invention is not limited to the Examples below.

### Example 1

### Manufacturing of Cemented Carbide

A tungsten carbide (WC) powder, a Co powder with an average particle diameter of 1.5 μm, a Ni powder with an average particle diameter of 1.5 μm, a TiC powder with an average particle diameter of 1.2 μm, a NbC powder with an average particle diameter of 1.0 μm, a TaC powder with an average particle diameter of 1.0 μm, a ZrC powder with an average particle diameter of 4.0 μm, and a Cr₃C₂ powder with an average particle diameter of 1.5 μm, commercially available as the raw material powders were prepared. Here, for the WC powders, three types of types A to C having different carbon content ratios as shown in Table 1 were prepared. The type and the average particle diameter used in each sample are shown in Table 3. It should be noted that the average particle diameter of the raw material powder was measured by the Fisher method (Fisher Sub-Sieve Sizer (FSSS)) described in the American Society for Testing and Materials (ASTM) standard B330.

With regard to inventive products 1 to 22 and comparative products 1 to 14, the prepared raw material powders were weighed and blended so as to achieve the compositions shown in Table 2 (Blending step). The blended raw material powder was accommodated in a pot made of stainless steel together with an acetone solvent and balls made of cemented carbide, and mixing and grinding were performed by a planetary ball mill for the time shown in Table 3, resulting in a mixture (mixing step). The resulting mixture was heated at 100° C. or less, and the solvent was evaporated while drying, resulting in a dry mixture (drying step). Further, 1.5 mass % of paraffin wax was blended in an amount to 100 mass % of the resulting dried mixture, followed by press molding into a shape of a tool under a pressure of 120 MPa using a predetermined mold, resulting in a molded body of the mixture (molding step). As the mold, a mold whose shape after sintering becomes the ISO standard insert shape CNMG 120408 was used.

Then, the molded body was accommodated in the sintering furnace, and was raised in temperature from room temperature up to a temperature of 1300° C. in a vacuum equal to or lower than 70 Pa (first temperature raising step). Further, under an argon gas atmosphere of 800 kPa, the temperature was raised up to a sintering temperature of 1450° C. at a rate of 5° C./min (second temperature raising step). Thereafter, the molded body was held for 30 minutes at a sintering temperature of 1450° C. under an atmosphere of an argon gas of 200 kPa, thereby sintering the molded body. After sintering, the sintered body was cooled to 1250° C. at each rate shown in Table 3 under a mixed gas atmosphere of Ar and CO at a total pressure 200 kPa having the ratios of partial pressures shown in Table 3, (provided that the comparative products 8 to 11 were under an Ar gas atmosphere) (first cooling step). Further, the sintered body after the first cooling step was cooled down to 900° C. at a cooling rate of 50° C./min under an argon gas atmosphere at atmospheric pressure, and further was cooled down to room temperature (second cooling step).

In the foregoing manner, cemented carbide processed into a tool shape was formed. Further, the ridgeline portion of the cutting edge of the obtained cemented carbide was subjected to a honing treatment with a SiC brush.

TABLE 1
WC raw material powder

Content ratio (mass %)

| Type | W element | C element |
|---|---|---|
| A | 93.97 | 6.03 |
| B | 93.87 | 6.13 |
| C | 93.77 | 6.23 |

TABLE 2

| | Blended composition (mass %) | | | | | | | |
|---|---|---|---|---|---|---|---|---|
| Sample No. | WC | Co | Ni | TiC | NbC | TaC | ZrC | Cr₃C₂ |
| Inventive product 1 | 87.0 | 10.0 | — | — | 2.0 | — | — | 1.0 |
| Inventive product 2 | 83.5 | 13.5 | — | 1.0 | — | 1.0 | — | 1.0 |
| Inventive product 3 | 80.5 | 7.0 | 7.0 | — | 2.0 | 2.0 | 0.5 | 1.0 |
| Inventive product 4 | 87.0 | 10.0 | — | — | 2.0 | — | — | 1.0 |
| Inventive product 5 | 87.0 | 10.0 | — | — | 2.0 | — | — | 1.0 |
| Inventive product 6 | 87.0 | 5.0 | 5.0 | — | 2.0 | — | — | 1.0 |
| Inventive product 7 | 87.0 | 10.0 | — | — | 2.0 | — | — | 1.0 |
| Inventive product 8 | 87.0 | 10.0 | — | — | 2.0 | — | — | 1.0 |
| Inventive product 9 | 87.0 | 10.0 | — | — | 2.0 | — | — | 1.0 |
| Inventive product 10 | 87.0 | 10.0 | — | — | 2.0 | — | — | 1.0 |
| Inventive product 11 | 92.0 | 7.0 | — | — | — | 0.5 | 0.1 | 0.4 |
| Inventive product 12 | 94.5 | 4.5 | — | — | — | 0.5 | 0.1 | 0.4 |
| Inventive product 13 | 92.8 | 7.0 | — | — | — | — | — | 0.2 |
| Inventive product 14 | 92.0 | 7.0 | — | — | — | 0.5 | 0.1 | 0.4 |
| Inventive product 15 | 92.0 | 7.0 | — | — | — | 0.5 | 0.1 | 0.4 |
| Inventive product 16 | 92.0 | 7.0 | — | — | — | 0.5 | 0.1 | 0.4 |
| Inventive product 17 | 92.0 | 7.0 | — | — | — | 0.5 | 0.1 | 0.4 |
| Inventive product 18 | 92.0 | 7.0 | — | — | — | 0.5 | 0.1 | 0.4 |
| Inventive product 19 | 92.0 | 7.0 | — | — | — | 0.5 | 0.1 | 0.4 |
| Inventive product 20 | 92.0 | 7.0 | — | — | — | 0.5 | 0.1 | 0.4 |
| Inventive product 21 | 92.0 | 7.0 | — | — | — | 0.5 | 0.1 | 0.4 |
| Inventive product 22 | 92.0 | 7.0 | — | — | — | 0.5 | 0.1 | 0.4 |
| Comparative product 1 | 82.0 | 12.0 | 4.0 | 0.5 | — | 0.5 | — | 1.0 |
| Comparative product 2 | 82.0 | 5.0 | 5.0 | 2.5 | 2.0 | 2.0 | 0.5 | 1.0 |
| Comparative product 3 | 79.0 | 15.0 | — | 1.5 | 1.5 | 1.5 | 0.5 | 1.0 |
| Comparative product 4 | 88.0 | 10.0 | — | — | 1.0 | — | — | 1.0 |
| Comparative product 5 | 87.0 | 10.0 | — | — | 2.0 | — | — | 1.0 |
| Comparative product 6 | 87.0 | 10.0 | — | — | 2.0 | — | — | 1.0 |
| Comparative product 7 | 87.0 | 10.0 | — | — | 2.0 | — | — | 1.0 |
| Comparative product 8 | 96.8 | 3.0 | — | — | — | — | — | 0.2 |
| Comparative product 9 | 92.0 | 7.0 | — | — | — | 0.5 | 0.1 | 0.4 |
| Comparative product 10 | 92.0 | 7.0 | — | — | — | 0.5 | 0.1 | 0.4 |
| Comparative product 11 | 92.0 | 7.0 | — | — | — | 0.5 | 0.1 | 0.4 |
| Comparative product 12 | 92.0 | 7.0 | — | — | — | 0.5 | 0.1 | 0.4 |
| Comparative product 13 | 92.0 | 7.0 | — | — | — | 0.5 | 0.1 | 0.4 |
| Comparative product 14 | 92.0 | 7.0 | — | — | — | 0.5 | 0.1 | 0.4 |

TABLE 3

| | WC raw material powder | | | First cooling step | |
|---|---|---|---|---|---|
| | | Average | Mixing | Partial | |
| | | particle | step | pressure | Cooling |
| | | diameter | Time | ratio | rate |
| Sample No. | Type | (μm) | (hour) | Ar:CO | (° C./min) |
| Inventive product 1 | B | 0.7 | 12 | 9:1 | 3.0 |
| Inventive product 2 | B | 0.7 | 12 | 9:1 | 3.0 |
| Inventive product 3 | B | 0.7 | 12 | 9:1 | 3.0 |
| Inventive product 4 | C | 0.7 | 12 | 8:2 | 3.0 |
| Inventive product 5 | C | 0.7 | 12 | 7:3 | 3.0 |
| Inventive product 6 | B | 0.7 | 6 | 9:1 | 3.0 |
| Inventive product 7 | B | 0.6 | 16 | 9:1 | 3.0 |
| Inventive product 8 | B | 0.6 | 12 | 9:1 | 3.0 |
| Inventive product 9 | B | 0.5 | 12 | 9:1 | 3.0 |
| Inventive product 10 | C | 0.7 | 12 | 8:2 | 1.0 |
| Inventive product 11 | B | 1.2 | 10 | 9:1 | 4.0 |
| Inventive product 12 | B | 1.2 | 10 | 9:1 | 4.0 |
| Inventive product 13 | B | 1.2 | 10 | 9:1 | 4.0 |
| Inventive product 14 | B | 1.2 | 10 | 9:1 | 5.0 |
| Inventive product 15 | B | 1.2 | 10 | 8:2 | 8.0 |
| Inventive product 16 | B | 1.2 | 10 | 9:1 | 4.0 |
| Inventive product 17 | C | 1.2 | 10 | 8:2 | 2.0 |
| Inventive product 18 | B | 1.2 | 10 | 9:1 | 4.0 |
| Inventive product 19 | B | 1.6 | 10 | 9:1 | 4.0 |
| Inventive product 20 | C | 1.7 | 10 | 8:2 | 3.0 |
| Inventive product 21 | C | 1.9 | 10 | 8:2 | 3.0 |
| Inventive product 22 | B | 1.7 | 10 | 8:2 | 5.0 |
| Comparative product 1 | B | 0.7 | 12 | 9:1 | 3.0 |
| Comparative product 2 | B | 0.7 | 12 | 9:1 | 3.0 |
| Comparative product 3 | B | 0.7 | 12 | 9:1 | 3.0 |
| Comparative product 4 | C | 0.7 | 12 | 7:3 | 1.0 |
| Comparative product 5 | C | 0.7 | 12 | 7:3 | 0.5 |
| Comparative product 6 | C | 0.4 | 24 | 7:3 | 2.0 |
| Comparative product 7 | C | 0.7 | 12 | 7:3 | 2.0 |
| Comparative product 8 | B | 1.2 | 10 | 9:1 | 4.0 |
| Comparative product 9 | C | 1.2 | 10 | 10:0 | 1.0 |
| Comparative product 10 | B | 1.2 | 10 | 10:0 | 5.0 |
| Comparative product 11 | A | 1.2 | 10 | 10:0 | 8.0 |
| Comparative product 12 | C | 1.2 | 10 | 10:0 | 8.0 |
| Comparative product 13 | C | 1.9 | 6 | 7:3 | 2.0 |
| Comparative product 14 | C | 2.3 | 10 | 7:3 | 2.0 |

### Composition of Cemented Carbide

The respective compositions and respective content ratios (mass %) of the obtained cemented carbide were determined in the following manner. Each cross sectional structure at at least arbitrary three sites (each cross sectional structure at a position at a depth of 500 μm from the surface toward the inside) in the inside of the resulting cemented carbide was observed with a scanning electron microscope (SEM) with an energy dispersive X-ray spectrometer (EDS), and each composition was measured by the EDS. From the results, the content ratio of each composition in each sample was determined.

As a more specific method, the cemented carbide was polished in a direction orthogonal to the surface thereof, resulting in a cross sectional structure. The resulting cross sectional structure was observed with a SEM. The cross sectional structure in a range of 50 μm×50 μm centering on the position at a depth of 500 μm from the surface toward the inside of the cemented carbide at a magnification of 2000 times, thereby performing area analysis by the EDS. The mass % of each composition was converted from the atomic % of the each composition obtained from the result of the area analysis, and the content ratio (mass %) of each composition was calculated. The average value of the content ratios of respective compositions obtained from the analyses of the 3 visual fields was referred to as the content ratio of each composition in respective samples. The results are shown in Table 4.

Similarly, the phase configuration of the cemented carbide was examined. All the obtained cemented carbide each include WC phases including tungsten carbide (WC), a binder phase bonding the WC phases, and hard phases. It was observed that r phases and free carbons were not precipitated (the total volume of the WC phases, the binder phases, and the hard phases is 100 vol % relative to 100 vol % of the entire cemented carbide). Further, in any cemented carbide, the main component of the binder phase was Co and Ni, or Co.

As a result of examination of the composition of the cemented carbide with the foregoing method, in the cemented carbide of the inventive product, the WC phase included WC, the binder phase included at least one selected from the group consisting of Co, Ni, and Fe, and the hard phase included at least one of a carbide, a nitride, and a carbonitride of one or more selected from the group consisting of Ti, V, Cr, Zr, Nb, Mo, Hf, and Ta, the content ratio of the WC phases was 80.0 mass % or more and 95.0 mass % or less, the content ratio of the binder phases was 4.0 mass % or more and 15.0 mass % or less, and the content ratio of the hard phases was 0.1 mass % or more and 6.0 mass % or less relative to 100 mass % of the entire cemented carbide.

TABLE 4

| | Cemented carbide | | | | | | | | | |
|---|---|---|---|---|---|---|---|---|---|---|
| | WC | Bonding phase | | | | | | | | |
| | phase | (mass %) | | | Hard phase (mass %) | | | | | |
| Sample No. | (mass %) | Total | Co | Ni | Total | TiC | NbC | TaC | ZrC | Cr₃C₂ |
| Inventive product 1 | 87.0 | 10.0 | 10.0 | — | 3.0 | — | 2.0 | — | — | 1.0 |
| Inventive product 2 | 83.5 | 13.5 | 13.5 | — | 3.0 | 1.0 | — | 1.0 | — | 1.0 |
| Inventive product 3 | 80.5 | 14.0 | 7.0 | 7.0 | 5.5 | — | 2.0 | 2.0 | 0.5 | 1.0 |
| Inventive product 4 | 87.0 | 10.0 | 10.0 | — | 3.0 | — | 2.0 | — | — | 1.0 |
| Inventive product 5 | 87.0 | 10.0 | 10.0 | — | 3.0 | — | 2.0 | — | — | 1.0 |
| Inventive product 6 | 87.0 | 10.0 | 5.0 | 5.0 | 3.0 | — | 2.0 | — | — | 1.0 |
| Inventive product 7 | 87.0 | 10.0 | 10.0 | — | 3.0 | — | 2.0 | — | — | 1.0 |
| Inventive product 8 | 87.0 | 10.0 | 10.0 | — | 3.0 | — | 2.0 | — | — | 1.0 |
| Inventive product 9 | 87.0 | 10.0 | 10.0 | — | 3.0 | — | 2.0 | — | — | 1.0 |
| Inventive product 10 | 87.0 | 10.0 | 10.0 | — | 3.0 | — | 2.0 | — | — | 1.0 |
| Inventive product 11 | 92.0 | 7.0 | 7.0 | — | 1.0 | — | — | 0.5 | 0.1 | 0.4 |
| Inventive product 12 | 94.5 | 4.5 | 4.5 | — | 1.0 | — | — | 0.5 | 0.1 | 0.4 |
| Inventive product 13 | 92.8 | 7.0 | 7.0 | — | 0.2 | — | — | — | — | 0.2 |
| Inventive product 14 | 92.0 | 7.0 | 7.0 | — | 1.0 | — | — | 0.5 | 0.1 | 0.4 |
| Inventive product 15 | 92.0 | 7.0 | 7.0 | — | 1.0 | — | — | 0.5 | 0.1 | 0.4 |
| Inventive product 16 | 92.0 | 7.0 | 7.0 | — | 1.0 | — | — | 0.5 | 0.1 | 0.4 |
| Inventive product 17 | 92.0 | 7.0 | 7.0 | — | 1.0 | — | — | 0.5 | 0.1 | 0.4 |
| Inventive product 18 | 92.0 | 7.0 | 7.0 | — | 1.0 | — | — | 0.5 | 0.1 | 0.4 |
| Inventive product 19 | 92.0 | 7.0 | 7.0 | — | 1.0 | — | — | 0.5 | 0.1 | 0.4 |
| Inventive product 20 | 92.0 | 7.0 | 7.0 | — | 1.0 | — | — | 0.5 | 0.1 | 0.4 |
| Inventive product 21 | 92.0 | 7.0 | 7.0 | — | 1.0 | — | — | 0.5 | 0.1 | 0.4 |
| Inventive product 22 | 92.0 | 7.0 | 7.0 | — | 1.0 | — | — | 0.5 | 0.1 | 0.4 |
| Comparative product 1 | 82.0 | 16.0 | 12.0 | 4.0 | 2.0 | 0.5 | — | 0.5 | — | 1.0 |
| Comparative product 2 | 82.0 | 10.0 | 5.0 | 5.0 | 8.0 | 2.5 | 2.0 | 2.0 | 0.5 | 1.0 |
| Comparative product 3 | 79.0 | 15.0 | 15.0 | — | 6.0 | 1.5 | 1.5 | 1.5 | 0.5 | 1.0 |
| Comparative product 4 | 88.0 | 10.0 | 10.0 | — | 2.0 | — | 1.0 | — | — | 1.0 |
| Comparative product 5 | 87.0 | 10.0 | 10.0 | — | 3.0 | — | 2.0 | — | — | 1.0 |
| Comparative product 6 | 87.0 | 10.0 | 10.0 | — | 3.0 | — | 2.0 | — | — | 1.0 |
| Comparative product 7 | 87.0 | 10.0 | 10.0 | — | 3.0 | — | 2.0 | — | — | 1.0 |
| Comparative product 8 | 96.8 | 3.0 | 3.0 | — | 0.2 | — | — | — | — | 0.2 |
| Comparative product 9 | 92.0 | 7.0 | 7.0 | — | 1.0 | — | — | 0.5 | 0.1 | 0.4 |
| Comparative product 10 | 92.0 | 7.0 | 7.0 | — | 1.0 | — | — | 0.5 | 0.1 | 0.4 |
| Comparative product 11 | 92.0 | 7.0 | 7.0 | — | 1.0 | — | — | 0.5 | 0.1 | 0.4 |
| Comparative product 12 | 92.0 | 7.0 | 7.0 | — | 1.0 | — | — | 0.5 | 0.1 | 0.4 |
| Comparative product 13 | 92.0 | 7.0 | 7.0 | — | 1.0 | — | — | 0.5 | 0.1 | 0.4 |
| Comparative product 14 | 92.0 | 7.0 | 7.0 | — | 1.0 | — | — | 0.5 | 0.1 | 0.4 |

### Length of Grain Boundary Between Adjacent WC Grains and Length of Σ2 Grain Boundary

The length of the grain boundary between adjacent WC grains was measured for the cemented carbide obtained as described above in the following manner. Specifically, the cemented carbide was polished in a direction orthogonal to the surface thereof, and the resulting cross section was polished using colloidal silica, resulting in the observation surface of a mirror-polished cross sectional structure. The observation surface thus obtained was observed using a SEM of SU6600 (manufactured by Hitachi High-Tech Corporation) equipped with an electron backscatter diffraction (EBSD) apparatus (manufactured by TexSEM Laboratories, Co.). The normal to the observation surface was tilted by 70° with respect to an incident beam, and analysis was conducted by applying an electron beam at an acceleration voltage of 15 kV and an irradiation current of 1.0 nA.

The data collection was conducted at a step size of 0.01 μm/step (distance between measurement points) with a range of 15 μm×25 μm as the measurement range so that the position at about 500 μm from the surface toward the inside of the cemented carbide may become the center of the visual field. For each measurement point within the measurement range, a Kikuchi pattern was obtained from the reflected electrons of the electron beam applied onto the observation surface, and the crystal orientation at each measurement point was measured. By analyzing the obtained orientation data using commercially available software, the misorientations between adjacent measurement points on the WC phase within the measurement range was analyzed. When the misorientation between adjacent measurement points was 5° or more, the boundary between the measurement points was defined as a grain boundary (grain boundary A) between adjacent WC grains, and the total length of the grain boundaries A and the total length of the Σ2 grain boundaries within the measurement range were determined. From the obtained result, the ratio of the total length of the Σ2 grain boundaries to the total length of the grain boundaries A was calculated. The same analysis was conducted for the observation surfaces of a total of ten visual fields, and the average value of the obtained values was referred to as the ratio of the length of the Σ2 grain boundaries to 100% of the length of the grain boundaries A in each sample (hereinafter also referred to as “Σ2 grain boundary/grain boundary A”). The results are shown in Table 5.

Grain Diameter D_{10A} and Grain Diameter D_{90A}

The grain diameter D_{10A} providing a cumulative value of 10% and the grain diameter D_{90A} providing a cumulative value of 90%, on the basis of the number of grains using the grain boundary A, were determined by analyzing the crystal orientation for each measurement point obtained for determining the above (Σ2 grain boundary/grain boundary A). Specifically, in the observation surface, the minimum region surrounded by only the grain boundary A of the WC phase, the boundary between the grain boundary A and the WC phase and other phases than the WC phase, or only the boundary between the WC phase and other phases than the WC phase was defined as one WC grain (grain A). Here, by analysis using commercially available software, the areas occupied by the grains A were individually determined in the observation surface, and the diameter of a circle with an area equal to the area was referred to as the grain diameter of each individual grain A. The grain diameters of all the grains A present within the measurement range were determined, and a grain number-based grain size distribution graph was formed and analyzed, thereby calculating the grain diameter D_{10A} providing a cumulative value of 10%, and the grain diameter D_{90A} providing a cumulative value of 90%. Incidentally, with regard to the grain diameter D_{10A} and the grain diameter D_{90A}, the proportion of the number of the grains A with a grain diameter equal to or less than D_{10A} is 10%, and the proportion of the number of grains A with a grain diameter equal to or less than D_{90A} is 90%, relative to 100% of the number of all the grains A present in the measurement range. The same analysis was performed on the observation surfaces of a total of 10 visual fields. Thus, the average values of the obtained values were referred to as D_{10A} and D_{90A} in each sample. The results are shown in Table 5.

Grain Diameter D_{10B} and Grain Diameter D_{90B}, Ratio (D_{10B}/D_{10A}) and Ratio (D_{90B}/D_{90A})

The grain diameter D_{10B} providing a cumulative value of 10% and the grain diameter D_{90B} providing a cumulative value of 90%, on the basis of the number of grains using the grain boundary B, were determined by analyzing the crystal orientation for each measurement point obtained for determining the above (Σ2 grain boundary/grain boundary A). Specifically, in the observation surface, the minimum region surrounded by only the grain boundary B of the WC phase, the boundary between the grain boundary B and the WC phase and other phases than the WC phase, or only the boundary between the WC phase and other phases than the WC phase was defined as one grain B. Here, by analysis using commercially available software, the areas occupied by the grains B were individually determined in the observation surface, and the diameter of a circle with an area equal to the area was referred to as the grain diameter of each individual grain B. The grain diameters of all the grains B present within the measurement range were determined, and a grain number-based grain size distribution graph was formed and analyzed, thereby calculating the grain diameter D_{10B} providing a cumulative value of 10%, and the grain diameter D_{90B} providing a cumulative value of 90%. Incidentally, with regard to the grain diameter D_{10B} and grain diameter D_{90B}, the proportion of the number of the grains B with a grain diameter equal to or less than D_{10B} is 10%, and the proportion of the number of grains B with a grain diameter equal to or less than D_{90B} is 90%, relative to 100% of the number of all the grains B present in the measurement range. The same analysis was performed on the observation surfaces of a total of 10 visual fields. Thus, the average values of the obtained values were referred to as D_{10B} and D_{90B} in each sample. Herein, the grain boundary B indicates the grain boundary except for the Σ2 grain boundary of the grain boundary A. Furthermore, from D_{10A}, D_{90A}, D_{10B}, and D_{90B}, in each sample obtained, the ratio (D_{10B}/D_{10A}) and the ratio (D_{90B}/D_{90A}) for each sample were calculated. The results are shown in Table 5.

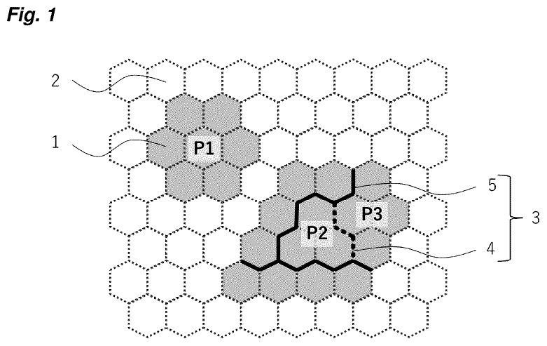

The method for identifying the grains A and the grains B by EBSD measurement will be described with reference to the schematic diagram of FIG. 1 as an example. In FIG. 1, the measurement surface is divided by pixels in a regular hexagonal shape, and each pixel corresponds to one measurement point. Of respective measure points, the measure point identified as the WC phase by EBSD measurement is indicated with a gray measurement point 1, and the measurement point identified as a phase other than the WC phase is indicated with a white measurement point 2. A grain boundary 3 that is the grain boundary A may be present between the measurement points in the adjacent WC phases, and the grain boundary 3 is further classified on the basis of the crystal misorientations. Specifically, of the grain boundaries 3, a grain boundary 4 which is the Σ2 grain boundary is indicated with a thick broken line, and a grain boundary 5 which is the grain boundary B is indicated with a thick solid line. Here, a reference sign P1 is a set including seven measurement points in the WC phase, and represents the grain A surrounded only by the boundary between the WC phase and the phase other than the WC phase. A reference sign P2 represents a set including three measurement points in the WC phase, and represents the grain A surrounded by only the grain boundary A. Further, a reference sign P3 is a set including four measurement points in the WC phase, and represents the grain A surrounded by the grain boundary A and the boundary between the WC phase and phases other than the WC phase. Furthermore, a set of the reference sign P2 and the reference sign P3 is a set including seven measurement points in the WC phase, and represents the grain B surrounded by the grain boundary B and the boundary between the WC phase and phases other than the WC phase.

TABLE 5

| | Σ2 grain | | | | |
|---|---|---|---|---|---|
| | boundary/grain | D10B/ | D90B/ | D10A | D90A |
| Sample No. | boundary A (%) | D10A | D90A | (μm) | (μm) |
| Inventive product 1 | 10.8 | 1.49 | 1.08 | 0.08 | 0.76 |
| Inventive product 2 | 10.8 | 1.48 | 1.07 | 0.08 | 0.77 |
| Inventive product 3 | 10.9 | 1.51 | 1.08 | 0.08 | 0.76 |
| Inventive product 4 | 12.2 | 1.72 | 1.19 | 0.08 | 0.77 |
| Inventive product 5 | 14.2 | 1.84 | 1.18 | 0.08 | 0.77 |
| Inventive product 6 | 11.1 | 1.51 | 1.07 | 0.10 | 0.80 |
| Inventive product 7 | 11.0 | 1.52 | 1.09 | 0.06 | 0.62 |
| Inventive product 8 | 10.9 | 1.48 | 1.07 | 0.07 | 0.64 |
| Inventive product 9 | 10.8 | 1.48 | 1.08 | 0.05 | 0.54 |
| Inventive product 10 | 14.6 | 1.83 | 1.25 | 0.08 | 0.76 |
| Inventive product 11 | 8.5 | 1.43 | 1.03 | 0.16 | 1.27 |
| Inventive product 12 | 8.6 | 1.45 | 1.04 | 0.16 | 1.29 |
| Inventive product 13 | 8.4 | 1.43 | 1.04 | 0.16 | 1.28 |
| Inventive product 14 | 6.2 | 1.31 | 1.02 | 0.16 | 1.25 |
| Inventive product 15 | 8.4 | 1.34 | 1.02 | 0.16 | 1.28 |
| Inventive product 16 | 8.4 | 1.42 | 1.03 | 0.16 | 1.28 |
| Inventive product 17 | 13.6 | 1.75 | 1.24 | 0.16 | 1.27 |
| Inventive product 18 | 8.2 | 1.42 | 1.04 | 0.16 | 1.26 |
| Inventive product 19 | 8.0 | 1.45 | 1.03 | 0.20 | 1.65 |
| Inventive product 20 | 13.2 | 1.50 | 1.11 | 0.24 | 1.80 |
| Inventive product 21 | 13.1 | 1.49 | 1.10 | 0.28 | 1.96 |
| Inventive product 22 | 9.2 | 1.42 | 1.07 | 0.20 | 1.78 |
| Comparative product 1 | 11.0 | 1.50 | 1.08 | 0.08 | 0.76 |
| Comparative product 2 | 11.1 | 1.49 | 1.07 | 0.08 | 0.77 |
| Comparative product 3 | 11.0 | 1.51 | 1.08 | 0.08 | 0.77 |
| Comparative product 4 | 16.7 | 1.91 | 1.30 | 0.08 | 0.77 |
| Comparative product 5 | 17.4 | 1.96 | 1.43 | 0.08 | 0.76 |
| Comparative product 6 | 16.0 | 1.88 | 1.26 | 0.03 | 0.41 |
| Comparative product 7 | 16.3 | 1.89 | 1.27 | 0.08 | 0.77 |
| Comparative product 8 | 8.5 | 1.44 | 1.04 | 0.16 | 1.26 |
| Comparative product 9 | 8.3 | 1.21 | 1.32 | 0.18 | 1.32 |
| Comparative product 10 | 6.7 | 1.12 | 1.16 | 0.17 | 1.30 |
| Comparative product 11 | 4.6 | 1.06 | 1.05 | 0.16 | 1.27 |
| Comparative product 12 | 6.6 | 1.10 | 1.15 | 0.16 | 1.29 |
| Comparative product 13 | 15.8 | 1.86 | 1.27 | 0.31 | 1.98 |
| Comparative product 14 | 16.4 | 1.85 | 1.27 | 0.34 | 2.35 |

### Formation of Coating Layer

The manufactured cemented carbide was mounted on a holder inside of a reaction vessel of an arc ion plating apparatus. The pressure inside of the reaction vessel was evacuated to a vacuum of 1.0×10⁻² Pa or lower. The cemented carbide was heated to a temperature of 500° C. by a heater in a furnace. After the temperature of the cemented carbide reached 500° C., an Ar gas was introduced into the reaction vessel until the pressure inside of the reaction vessel reached 3.0 Pa. A bias voltage of −400 V was applied to the cemented carbide in the reaction vessel, and a current of 40 A was passed through the tungsten filament in the reaction vessel, thus performing an Ar ion bombardment treatment on the surface of the cemented carbide. After the Ar ion bombardment treatment, an Ar gas was discharged to perform evacuation until the pressure in the reaction vessel reached a vacuum of 5.0×10⁻³ Pa or lower.

After the evacuation, the temperature of the cemented carbide was controlled so as to become 450° C., and a N₂ gas was introduced into the reaction vessel, resulting in a nitrogen atmosphere at a pressure of 3.0 Pa in the reaction vessel. Then, a bias voltage of −60 V was applied to the cemented carbide, and the metal evaporation source was evaporated by 150 A arc discharge. As a result of this, a coating layer was formed on the surface of the cemented carbide. After the formation of the coating layer, the sample was cooled. After the temperature of the sample became 100° C. or less, the sample was taken out of the reaction vessel. As the coating layer, a compound layer including (Ti_{0.5}Al_{0.5})N was formed on the surface of the cemented carbide so as to have an average thickness of 2.0 μm.

The composition of the coating layer was measured using the EDS attached to the TEM at the cross section perpendicular to the surface of the cemented carbide in the vicinity of the position of 50 μm from the ridgeline portion of the cutting edge of the surface opposed to the metal evaporation source of the tool toward the center portion. In addition, the average thickness of the entire coating layer was determined by observing the cross-sections at at least three positions in the above cross-sections by a TEM, and measuring the thickness of the entire coating layer, followed by calculating the arithmetic average value thereof.

Using the obtained sample, the following cutting test was performed, and evaluation was performed. The results are shown in Table 6.

### Cutting Test

Workpiece material: Inconel (registered trademark) 718,
Cutting material shape: Round bar,
Cutting speed: 80 m/m in,
Cut depth: 0.8 mm,
Feed: 0.25 mm/rev,
Coolant: Used,
Insert: CNMG 120408 (ISO standard),
Evaluation item: When the maximum flank wear width of the tool reached 0.3 mm or the tool fractured, the tool was regarded as reaching the tool life, and the processing time taken to reach the tool life was measured. In addition, the damage of the sample for which the flank wear width of the tool reached 0.3 mm and the end of the tool life was reached was referred to as “normal wear,” and the damage of the sample for which the tool fractured and reached the end of the tool life was referred to as “fracture.”

TABLE 6

| | Cutting test | |
|---|---|---|
| | Tool life | |
| Sample No. | (min) | Damage |
| Inventive product 1 | 17 | Normal wear |
| Inventive product 2 | 15 | Normal wear |
| Inventive product 3 | 16 | Normal wear |
| Inventive product 4 | 21 | Normal wear |
| Inventive product 5 | 22 | Normal wear |
| Inventive product 6 | 17 | Normal wear |
| Inventive product 7 | 19 | Normal wear |
| Inventive product 8 | 18 | Normal wear |
| Inventive product 9 | 20 | Normal wear |
| Inventive product 10 | 20 | Normal wear |
| Inventive product 11 | 21 | Normal wear |
| Inventive product 12 | 23 | Normal wear |
| Inventive product 13 | 20 | Normal wear |
| Inventive product 14 | 15 | Normal wear |
| Inventive product 15 | 17 | Normal wear |
| Inventive product 16 | 19 | Normal wear |
| Inventive product 17 | 23 | Normal wear |
| Inventive product 18 | 18 | Normal wear |
| Inventive product 19 | 19 | Normal wear |
| Inventive product 20 | 16 | Normal wear |
| Inventive product 21 | 15 | Normal wear |
| Inventive product 22 | 17 | Normal wear |
| Comparative product 1 | 13 | Normal wear |
| Comparative product 2 | 7 | Fracture |
| Comparative product 3 | 13 | Normal wear |
| Comparative product 4 | 8 | Fracture |
| Comparative product 5 | 6 | Fracture |
| Comparative product 6 | 9 | Fracture |
| Comparative product 7 | 12 | Fracture |
| Comparative product 8 | 4 | Fracture |
| Comparative product 9 | 11 | Fracture |
| Comparative product 10 | 12 | Fracture |
| Comparative product 11 | 5 | Fracture |
| Comparative product 12 | 9 | Fracture |
| Comparative product 13 | 10 | Fracture |
| Comparative product 14 | 9 | Fracture |

From the results shown in Table 6, it was found that the cutting tools using the cemented carbide of the inventive product were more excellent in wear resistance and fracture resistance, and had a longer tool life than the cutting tool using the cemented carbide of the comparative product.

### Example 2

As a base material, the surfaces of the cemented carbide of inventive product 1 and the inventive product 11 obtained by the methods described above were subjected to an ion bombardment treatment in the same manner as in Example 1, and then, the coating layer described in Table 7 was formed by an arc ion plating method. When two or more layers are formed, the first layer, the second layer, and the third layer were formed in this order on the surface of the cemented carbide.

The coating layer was formed in the following manner. The cemented carbide of the inventive product 1 or the inventive product 11 was mounted to the holder of the reaction vessel of an arc ion plating apparatus. The pressure of the reaction vessel was set at a vacuum of 1.0×10⁻² Pa or less. The cemented carbide was heated to a temperature of 500° C. by a heater in a furnace. After heating, an Ar gas was introduced into the reaction vessel so that the pressure in the reaction vessel may become 3.0 Pa. A bias voltage of −400 V was applied to the cemented carbide in the reaction vessel, and a current of 40 A was passed through the tungsten filament in the reaction vessel, thereby performing an Ar ion bombardment treatment on the surface of the cemented carbide. After the Ar ion bombardment treatment, the Ar gas was discharged until the pressure in the reaction vessel reached a vacuum of 5.0×10⁻³ Pa or lower. After the evacuation, the temperature of the cemented carbide was controlled so as to be 450° C., and a N₂ gas was introduced into the reaction vessel, resulting in a nitrogen atmosphere at a pressure of 3.0 Pa in the reaction vessel. Herein, only when the second layer of the inventive product 23 and the second layer of the inventive product 29 were formed, a mixed gas of a N₂ gas, an Ar gas, and an acetylene (C₂H₂) gas at a volume ratio of 45:40:15 was introduced, thereby setting the pressure in the reaction vessel to 3.0 Pa. Then, a bias voltage of −60 V was applied to the cemented carbide and the metal evaporation source was evaporated by 150 A arc discharge, thereby forming a coating layer on the surface of the cemented carbide. As the metal evaporation source, those corresponding to the metal components of respective layers shown in Table 7 were used. After the formation of the coating layer, the sample was cooled. After the temperature of the sample became 100° C. or less, the sample was taken out of the reaction vessel. Herein, in forming the second layer of the inventive product 34, (Ti_{0.5}Al_{0.5})N and (Al_{0.7}Ti_{0.3})N 30 nm per layer were formed alternately and repeatedly, thereby achieving the average thickness of the second layer.

The composition of each layer of the coating layer was measured, using the EDS attached to the TEM, at a cross section perpendicular to the surface of the cemented carbide in the vicinity of the position of 50 μm from the ridgeline portion of the cutting edge of the surface opposed to the metal evaporation source of the tool toward the center portion. In addition, the average thickness of respective layers of the coating layer and the average thickness of the entire coating layer were determined by observing the cross sections at at least three positions in the above-mentioned cross section by a TEM, and measuring the thickness of the compound layer and the thickness of the entire coating layer, followed by calculation of the arithmetic average value thereof. The results are shown in Table 7. Incidentally, the composition ratio of the metal elements in the compound layer in Table 7 indicates the atomic ratio of each metal element or metalloid element to the whole metal elements and metalloid elements in the metal compound constituting the compound layer.

Also, using the obtained samples, a cutting test was performed in the same manner as in the cutting test, thereby evaluating the inventive products 23 to 34. The results are shown in Table 8.

TABLE 7

| | | Coating layer | | | | | | |
|---|---|---|---|---|---|---|---|---|
| | | | | | | | | Average |
| | | | | | | | | thickness |
| | | | | | | | | of the |
| | | First layer | | Second layer | | Third layer | | entire |
| | | | Average | | Average | | Average | coating |
| | | | thickness | | thickness | | thickness | layer |
| Sample No. | Cemented carbide | Composition | (μm) | Composition | (μm) | Composition | (μm) | (μm) |
| Inventive product 23 | Inventive product 1 | TiN | 0.5 | TiCN | 3.5 | — | — | 4.0 |
| Inventive product 24 | Inventive product 1 | (Ti_{0.5}Al_{0.5})N | 1.0 | (Al_{0.6}Ti_{0.4})N | 5.0 | (Al_{0.8}Cr_{0.2})N | 1.5 | 7.5 |
| Inventive product 25 | Inventive product 1 | CrN | 0.5 | (Al_{0.65}Ti_{0.25}Si_{0.1})N | 2.0 | — | — | 2.5 |
| Inventive product 26 | Inventive product 1 | (Al_{0.67}Ti_{0.33})N | 3.8 | (Ti_{0.9}Si_{0.1})N | 0.2 | — | — | 4.0 |
| Inventive product 27 | Inventive product 1 | (Ti_{0.5}Al_{0.5})N | 0.3 | (Ti_{0.6}Al_{0.3}W_{0.1})N | 3.0 | NbN | 0.2 | 3.5 |
| Inventive product 28 | Inventive product 1 | (Al_{0.6}Ti_{0.4})N | 0.5 | (Al_{0.8}Ti_{0.2})N | 1.0 | — | — | 1.5 |
| Inventive product 29 | Inventive product 11 | TiN | 0.5 | TiCN | 3.5 | — | — | 4.0 |
| Inventive product 30 | Inventive product 11 | (Ti_{0.5}Al_{0.5})N | 1.0 | (Al_{0.6}Ti_{0.4})N | 5.0 | (Al_{0.8}Cr_{0.2})N | 1.5 | 7.5 |
| Inventive product 31 | Inventive product 11 | (Al_{0.6}Ti_{0.4})N | 0.5 | (Al_{0.65}Ti_{0.25}Si_{0.1})N | 2.0 | — | — | 2.5 |
| Inventive product 32 | Inventive product 11 | (Al_{0.67}Ti_{0.33})N | 3.8 | (Ti_{0.9}Si_{0.1})N | 0.2 | — | — | 4.0 |
| Inventive product 33 | Inventive product 11 | (Ti_{0.5}Al_{0.5})N | 0.3 | (Ti_{0.6}Al_{0.3}W_{0.1})N | 3.0 | NbN | 0.2 | 3.5 |
| Inventive product 34 | Inventive product 11 | (Al_{0.7}Cr_{0.3})N | 0.2 | (Ti_{0.5}Al_{0.5})N/ | 1.8 | — | — | 2.0 |
| | | | | (Al_{0.7}Ti_{0.3})N | | | | |

TABLE 8

| | Cutting test | |
|---|---|---|
| | Tool life | |
| Sample No. | (min) | Damage |
| Inventive product 23 | 18 | Normal wear |
| Inventive product 24 | 21 | Normal wear |
| Inventive product 25 | 19 | Normal wear |
| Inventive product 26 | 20 | Normal wear |
| Inventive product 27 | 19 | Normal wear |
| Inventive product 28 | 19 | Normal wear |
| Inventive product 29 | 22 | Normal wear |
| Inventive product 30 | 24 | Normal wear |
| Inventive product 31 | 26 | Normal wear |
| Inventive product 32 | 25 | Normal wear |
| Inventive product 33 | 23 | Normal wear |
| Inventive product 34 | 23 | Normal wear |

From the results shown in Table 8, it was found that the inventive product using the coated cemented carbide of the present invention has excellent wear resistance and fracture resistance, and has a long tool life.

A tool having the cemented carbide or the coated cemented carbide of the present invention is excellent in wear resistance and fracture resistance, and thereby can more extend the tool life than in the prior art, and hence is highly industrially applicable in terms of the respects.

What is claimed is:

1. A cemented carbide comprising a WC phase, a binder phase, and a hard phase, wherein
the WC phase comprises WC,
the binder phase comprises at least one selected from the group consisting of Co, Ni, and Fe,
the hard phase comprises at least one of a carbide, a nitride, and a carbonitride of at least one element selected from the group consisting of Ti, V, Cr, Zr, Nb, Mo, Hf, and Ta,
the content ratio of the WC phases is 80.0 mass % or more and 95.0 mass % or less, the content ratio of the binder phases is 4.0 mass % or more and 15.0 mass % or less, and the content ratio of the hard phases is 0.1 mass % or more and 6.0 mass % or less, relative to 100 mass % of the entire cemented carbide,
wherein in the WC phase, a region between measurement points where a misorientation between adjacent measurement points measured by an electron backscatter diffraction (EBSD) method is 5° or more is referred to as a grain boundary between adjacent WC grains, and the grain boundary between WC grains is referred to as a grain boundary A, a grain boundary except for a Σ2 grain boundary of the grain boundary A is referred to as a grain boundary B, a grain diameter at which a cumulative value in a grain number-based grain size distribution using the grain boundary A becomes 10% is referred to as D_{10A}, and a grain diameter at which a cumulative value in a grain number-based grain size distribution using the grain boundary B becomes 10% is referred to as D_{10B},
a ratio of the D_{10B} to the D_{10A} (D_{10B}/D_{10A}) is 1.30 or more and 2.00 or less, and
a ratio of a length of the Σ2 grain boundary to 100% of a length of the grain boundary A is 5.0% or more and less than 15.0%.

2. The cemented carbide according to claim 1, wherein a ratio of D_{90B} to D_{90A} (D_{90B}/D_{90A}) is less than 1.30, where D_{90A} represents a grain diameter at which the cumulative value in the grain number-based grain size distribution using the grain boundary A becomes 90%, and D_{90B} represents a grain diameter at which the cumulative value in the grain number-based grain size distribution using the grain boundary B becomes 90%.

3. The cemented carbide according to claim 2, wherein the D_{90A} is 0.50 μm or more and 2.00 μm or less.

4. The cemented carbide according to claim 1, wherein the D_{10A} is 0.05 μm or more and 0.30 μm or less.

5. A coated cemented carbide comprising the cemented carbide according to claim 1, and a coating layer disposed on a surface of the cemented carbide,
wherein the coating layer is a monolayer or a lamination of two or more layers including a compound including at least one element selected from the group consisting of Ti, Zr, Hf, V, Nb, Ta, Cr, Mo, W, Al, Si, and Y, and at least one element selected from the group consisting of C, N, O, and B, and
an average thickness of the entire coating layer is 0.5 μm or more and 10.0 μm or less.

6. A tool comprising the cemented carbide according to claim 1.

7. The cemented carbide according to claim 2, wherein the D_{10A} is 0.05 μm or more and 0.30 μm or less.

8. The cemented carbide according to claim 3, wherein the D_{10A} is 0.05 μm or more and 0.30 μm or less.

9. A coated cemented carbide comprising the cemented carbide according to claim 2, and a coating layer disposed on a surface of the cemented carbide,
wherein the coating layer is a monolayer or a lamination of two or more layers including a compound including at least one element selected from the group consisting of Ti, Zr, Hf, V, Nb, Ta, Cr, Mo, W, Al, Si, and Y, and at least one element selected from the group consisting of C, N, O, and B, and
an average thickness of the entire coating layer is 0.5 μm or more and 10.0 μm or less.

10. A coated cemented carbide comprising the cemented carbide according to claim 3, and a coating layer disposed on a surface of the cemented carbide,
wherein the coating layer is a monolayer or a lamination of two or more layers including a compound including at least one element selected from the group consisting of Ti, Zr, Hf, V, Nb, Ta, Cr, Mo, W, Al, Si, and Y, and at least one element selected from the group consisting of C, N, O, and B, and
an average thickness of the entire coating layer is 0.5 μm or more and 10.0 μm or less.

11. A coated cemented carbide comprising the cemented carbide according to claim 4, and a coating layer disposed on a surface of the cemented carbide,
wherein the coating layer is a monolayer or a lamination of two or more layers including a compound including at least one element selected from the group consisting of Ti, Zr, Hf, V, Nb, Ta, Cr, Mo, W, Al, Si, and Y, and at least one element selected from the group consisting of C, N, O, and B, and
an average thickness of the entire coating layer is 0.5 μm or more and 10.0 μm or less.

12. A coated cemented carbide comprising the cemented carbide according to claim 7, and a coating layer disposed on a surface of the cemented carbide,
wherein the coating layer is a monolayer or a lamination of two or more layers including a compound including at least one element selected from the group consisting of Ti, Zr, Hf, V, Nb, Ta, Cr, Mo, W, Al, Si, and Y, and at least one element selected from the group consisting of C, N, O, and B, and
an average thickness of the entire coating layer is 0.5 μm or more and 10.0 μm or less.

13. A coated cemented carbide comprising the cemented carbide according to claim 8, and a coating layer disposed on a surface of the cemented carbide,
wherein the coating layer is a monolayer or a lamination of two or more layers including a compound including at least one element selected from the group consisting of Ti, Zr, Hf, V, Nb, Ta, Cr, Mo, W, Al, Si, and Y, and at least one element selected from the group consisting of C, N, O, and B, and
an average thickness of the entire coating layer is 0.5 μm or more and 10.0 μm or less.

14. A tool comprising the cemented carbide according to claim 2.

15. A tool comprising the cemented carbide according to claim 7.

16. A tool comprising the cemented carbide according to claim 8.

17. A tool comprising the coated cemented carbide according to claim 5.

18. A tool comprising the coated cemented carbide according to claim 9.

19. A tool comprising the coated cemented carbide according to claim 12.

20. A tool comprising the coated cemented carbide according to claim 13.
